(19) United States
(12) Patent Application Publication
(10) Pub. No.: US 2015/0137117 A1
(43) Pub. Date: May 21, 2015

(54) DISPLAY PANEL

(71) Applicant: InnoLux Corporation, Jhu-Nan (TW)

(72) Inventor: Chia-Hao TSAI, Jhu-Nan (TW)

(21) Appl. No.: 14/535,029

(22) Filed: Nov. 6, 2014

(30) Foreign Application Priority Data
Nov. 15, 2013 (TW) 102141630

(51) Int. Cl. H01L 27/12; H01L 29/417

(52) U.S. Cl. CPC H01L 27/124; H01L 27/1225; H01L 29/41733
USPC 257/43

(57) ABSTRACT

A display panel includes a first substrate and a plurality of pixels disposed on the first substrate. At least one of the pixels includes a gate line region, an active layer, an etch stop layer, a first and second source/drain layer. The gate line region is disposed on the first substrate and includes a first region and a second region. The first region includes a first portion having a first width and the second region includes a second portion having a second width. The first width is greater than the second width. The active layer is disposed on the gate line region and includes a channel region disposed on the first region. The etch stop layer and first and second source/drain layers are disposed on the active layer, and the portion of the active layer between the first and second source/drain layers is the channel region.

### CROSS REFERENCE TO RELATED APPLICATIONS

This Non-provisional application claims priority under 35 U.S.C. §119(a) on Patent Application No(s). 102141630 filed in Taiwan, Republic of China on Nov. 15, 2013, the entire contents of which are hereby incorporated by reference.

### BACKGROUND OF THE INVENTION

1. Field of Invention

The invention relates to a display panel.

2. Related Art

Common display panels or devices encompass liquid crystal display (LCD) devices or organic light emitting diode (OLED) display devices. No matter what kind of display panel or device is, amorphous silicon (a-Si) thin film transistors (TFTs) or low temperature polycrystalline (LTPS) TFTs are required to serve as the switch elements for driving each pixel. Recently, many researches point out that the oxide semiconductor TFTs have higher carrier mobility than the a-Si TFTs and have greater threshold voltage uniformity than the LTPS TFTs. Therefore, oxide semiconductor has been used as the main material in partial display panels or devices currently.

FIG. 1A is a schematic top view of a part of a conventional display panel, and FIG. 1B is a schematic sectional diagram taken along the line A-A in FIG. 1A. As shown in FIGS. 1A and 1B, the pixel structure 2′ of the conventional display panel includes a gate G, a source S1 and a drain S2, and an active layer AL is disposed between the source S1 and the drain S2. The above-mentioned oxide semiconductor is used as the material of the active layer AL. For this kind of display panel including the oxide semiconductor, an etch stop layer ESL is required to protect the oxide semiconductor. Therefore, the area of the source S1 and drain S2 needs to be increased for the effective driving, and the overlap area between the gate G and the source S1 and between the gate G and the drain S2 will be thus increased. However, the increased overlap area will lead to the rising of the loading capacitance. Furthermore, according to the formula of the power consumption calculation: P=f*C*V², it can be known that the rising of the capacitance (C) will lead to the increase of the power consumption (P) and the unstable driving signal, so that the display panel will easily undergo the problem of abnormal display and display distortion. For a 7 inch display panel with the resolution of 1200*1920 and 323 PPI (pixel per inch), it can be obtained that the capacitances Cs and Cg of each pixel are 33.5 fF and 24.5 fF, respectively, and the power consumption can be derived as about 1088 mW from the calculation according to the above-mentioned formula.

Therefore, it is an important subject to provide a display panel and a display device that can reduce the loading capacitance by the novel design to achieve the effectiveness of decreasing power consumption and stabilizing driving signal so as not to undergo the problem of abnormal display and display distortion.

### SUMMARY OF THE INVENTION

In view of the foregoing subject, an objective of the invention is to provide a display panel and a display device that can reduce the loading capacitance by a novel design to achieve the effectiveness of decreasing power consumption and stabilizing driving signal so as not to undergo the problem of abnormal display and display distortion.

To achieve the above objective, a display panel according to the invention comprises a first substrate, a plurality of pixels, a second substrate and a display medium. The pixels are disposed on the first substrate, and at least one of the pixels comprises a gate line region, an active layer, an etch stop layer and a first source/drain layer and a second source/drain layer. The gate line region is disposed on the first substrate and extended along a first direction and includes a first region and a second region. The first region includes a first portion and the second region includes a second portion, the first portion and the second portion have a first width and a second width along a second direction, respectively, the first direction is perpendicular to the second direction and the first width is greater than the second width. The active layer is disposed on the gate line region and includes a channel region disposed on the first portion. The etch stop layer is disposed on the active layer. The first source/drain layer and the second source/drain layer are disposed on the active layer and connected to the active layer. The portion of the active layer between the first source/drain layer and the second source/drain layer is the channel region. The second substrate is disposed on the first substrate. The display medium is disposed between the first and second substrates.

In one embodiment, the active layer further includes a non-channel region, the second region further has a first opening, and the non-channel region is disposed on the first opening.

In one embodiment, the active layer further includes a non-channel region, which is disposed on the second portion.

In one embodiment, the second region further has a second opening.

In one embodiment, the second width is 2 nm˜20 nm.

In one embodiment, the second width is 4 μm˜15 μm.

To achieve the above objective, a display panel according to the invention comprises a first substrate, a plurality of pixels, a second substrate and a display medium. The pixels are disposed on the first substrate, and at least one of the pixels comprises a gate line region, an active layer, an etch stop layer, a first source/drain layer, a second source/drain layer and a first insulation layer. The gate line region is disposed on the first substrate and extended along a first direction. The active layer is disposed on the gate line region. The etch stop layer is disposed on the active layer and has a first via and a second via. The first source/drain layer is disposed on the active layer and disposed in the first via to connect to the active layer. The second source/drain layer is disposed on the active layer and disposed in the second via to connect to the active layer. The first insulation layer is disposed on the first source/drain layer and the second source/drain layer and is disposed in the first via. The second substrate is disposed on the first substrate. The display medium is disposed between the first and second substrates.

In one embodiment, the portion of the active layer between the first source/drain layer and the second source/drain layer is a channel region, the active layer further includes a non-channel region, and the portion of the first insulation layer disposed in the first via is disposed on the non-channel region.

In one embodiment, at least one of the pixels further includes a pixel electrode layer disposed on the first insulation layer and in the second via.

In one embodiment, the portion of the active layer between the first source/drain layer and the second source/drain layer is a channel region, the active layer further includes a non-channel region, and the portion of the pixel electrode layer disposed in the second via is disposed on the non-channel region.

In one embodiment, the first source/drain layer has a third width of 5 μm 8.5 μm along the first direction.

To achieve the above objective, a display panel according to the invention comprises a first substrate, a plurality of pixels, a second substrate and a display medium. The pixels are disposed on the first substrate, and at least one of the pixels comprises a gate line region, an active layer, an etch stop layer, a first source/drain layer, a second source/drain layer, a first insulation layer and a pixel electrode layer. The gate line region is disposed on the first substrate and extended along a first direction. The active layer is disposed on the gate line region. The etch stop layer is disposed on the active layer and has a first via and a second via. The first source/drain layer is disposed on the active layer and disposed in the first via to connect to the active layer. The second source/drain layer is disposed on the active layer and disposed in the second via to connect to the active layer. The first insulation layer is disposed on the first source/drain layer and the second source/drain layer. The pixel electrode layer is disposed on the first insulation layer and in the second via. The second substrate is disposed on the first substrate. The display medium is disposed between the first and second substrates.

In one embodiment, the portion of the active layer between the first source/drain layer and the second source/drain layer is a channel region, the active layer further includes a non-channel region, and the portion of the pixel electrode layer disposed in the second via is disposed on the non-channel region.

In one embodiment, the first insulation layer is disposed in the first via.

In one embodiment, the portion of the active layer between the first source/drain layer and the second source/drain layer is a channel region, the active layer further includes a non-channel region, and the portion of the first insulation layer disposed in the first via is disposed on the non-channel region.

In one embodiment, the second source/drain layer has a fourth width of 5 μm 8.5 μm along the first direction.

To achieve the above objective, a display device according to the invention comprises any of the display panels of the above mentioned embodiments and a backlight module. The display panel is disposed on the backlight module.

As mentioned above, in the display panel and display device of the invention, the gate line region is divided into the first region and the second region, which include the first portion and the second portion, respectively, and the first width of the first portion is greater that the second width of the second portion. Or, the first insulation layer is disposed in the first via of the etch stop layer. Or, the pixel electrode layer is disposed in the second via of the etch stop layer. Accordingly, the overlap area of the first and second source/drain layers with the gate line region is reduced and less, in comparison with the overlap area of the source and drain with the gate of the conventional display panel. Therefore, the effectiveness of reducing the loading capacitance can be achieved, and the power consumption of the pixel driving can be thus reduced and the driving signals can be stabilized, so that the display panel and device wont′ easily undergo the problem of abnormal display and display distortion.

Moreover, the location of the second portion, the location of the first insulation layer contacting the active layer and the location of the pixel electrode layer contacting the active layer are all corresponding to the non-channel region, so the switch on of current in the channel region won't be influenced and the original current-voltage characteristic can be thus kept.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic top view of a part of a conventional display panel;

FIG. 1B is a schematic sectional diagram taken along the line A-A in FIG. 1A;

FIG. 2 is a schematic sectional diagram of a display panel according to an embodiment of the invention;

FIG. 3A is a schematic top view of a part of the pixels and the first substrate in FIG. 2 according to the first embodiment of the invention;

FIG. 3B is a schematic sectional diagram taken along the line A-A in FIG. 3A;

FIG. 4A is a schematic top view of a part of the pixels and the first substrate in FIG. 2 according to the second embodiment of the invention;

FIG. 4B is a schematic sectional diagram taken along the line A-A in FIG. 4A;

FIG. 4C is a schematic sectional diagram taken along the line A′-A′ in FIG. 4A;

FIG. 5A is a schematic diagram of a part of the pixels and the first substrate in FIG. 2 according to the third embodiment of the invention;

FIG. 5B is a schematic sectional diagram taken along the line A-A in FIG. 5A;

FIG. 6A is a schematic diagram of a part of the pixels and the first substrate in FIG. 2 according to the fourth embodiment of the invention;

FIG. 6B is a schematic sectional diagram taken along the line A-A in FIG. 6A;

FIG. 7A is a schematic diagram of a part of the pixels and the first substrate in FIG. 2 according to the fifth embodiment of the invention;

FIG. 7B is a schematic sectional diagram taken along the line A-A in FIG. 7A; and

FIG. 8 is a schematic sectional diagram of a display device according to an embodiment of the invention.

### DETAILED DESCRIPTION OF THE INVENTION

The present invention will be apparent from the following detailed description, which proceeds with reference to the accompanying drawings, wherein the same references relate to the same elements.

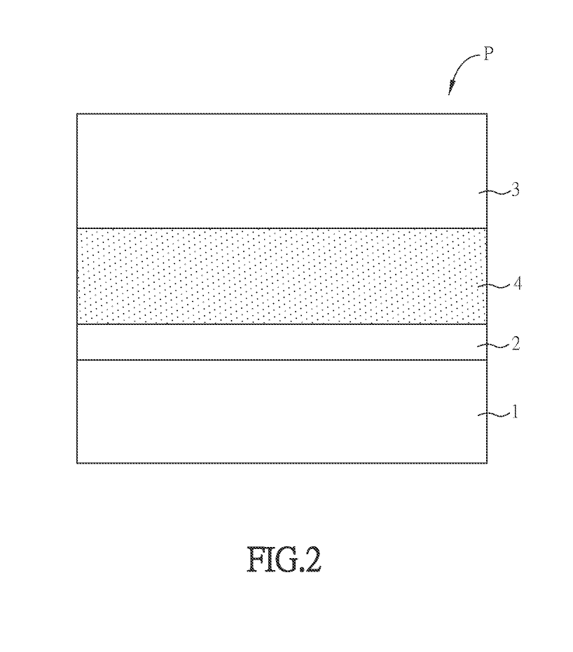

FIG. 2 is a schematic sectional diagram of a display panel according to an embodiment of the invention. As shown in FIG. 2, the display panel P of this embodiment includes a first substrate 1, a plurality of pixels 2, a second substrate 3 and a display medium 4. In detail, the first and second substrates 1 and 3 are transparent substrates for example (e.g. glass substrates or polymer substrates), and one of them can be configured with a color filter layer (not shown). The pixels 2 are disposed on the first substrate 1. The second substrate 3 is disposed on the first substrate 1 and the pixels are disposed between the first substrate 1 and the second substrate 3. The display medium 4 is disposed between the first substrate 1 and the second substrate 3, and can be a liquid crystal layer or an organic light emitting layer for example.

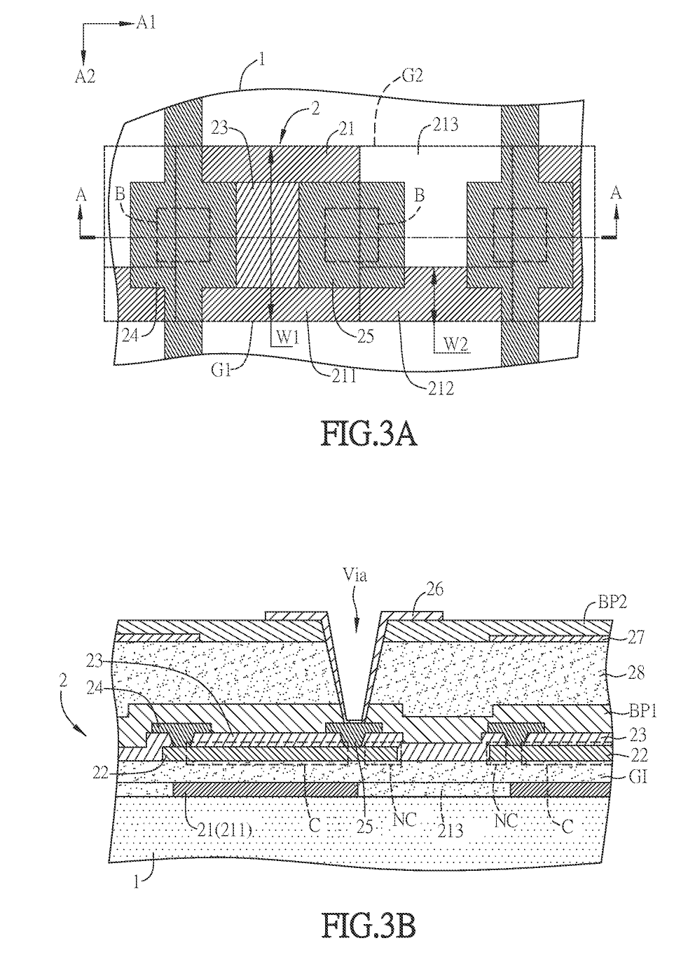

FIG. 3A is a schematic top view of a part of the pixels and the first substrate in FIG. 2 according to the first embodiment of the invention. As shown in FIGS. 2 and 3A, the pixels 2 are disposed on the first substrate 1, and each of the pixels 2 includes a gate line region 21, an active layer 22, an etch stop layer 23, a first source/drain layer 24 and a second source/drain layer 25. The gate line region 21 is disposed on the first substrate 1 along a first direction A1 and includes a first region G1 and a second region G2. The first region G1 has a first portion 211 and the second region G2 has a second portion 212. The first portion 211 and the second portion 212 have a first width W1 and a second width W2 along a second direction A2, respectively. The first direction A1 is substantially perpendicular to the second direction A2. The first width W1 is greater than the second width W2. In other words, the first region G1 and the second region G2 are defined according to the different widths of the gate line region 21 (i.e. the first width W1 and the second width W2). In this embodiment, the first region G1 is substantially the first portion 211, and the second region G2 is composed of the second portion 212 and a first opening 213. The material of the gate line area 21 is metal, so the gate line region 21 is also called the first metal layer.

FIG. 3B is a schematic sectional diagram taken along the line A-A in FIG. 3A. As shown in FIG. 3B, the active layer 22 is disposed on the gate line region 21 correspondingly and includes a channel region C disposed on the first portion 211. The active layer 22 further includes a non-channel region NC that is disposed on the first opening 213. The first source/drain layer 24 and the second source/drain layer 25 are disposed on the active layer 22 and connected to the active layer 22. The region B shown in FIG. 3A just refers to the region where the first source/drain layer 24 and second source/drain layer 25 contact with the active layer 22. The portion of the active layer 22 between the first source/drain layer 24 and the second source/drain layer 25 is the channel region C. In general, the channel region C refers to the region of the active layer 22 allowing the current flow, so it can be denoted by the shortest interval between the contact of the first source/drain layer 24 with the active layer 22 and the contact of the second source/drain layer 25 with the active layer 22. The portion of the active layer 22 excluding the first source/drain layer 24 and the second source/drain layer 25 is the non-channel region NC, and the first opening 213 is formed at the location corresponding to the non-channel region NC.

By referring to FIG. 3A also, the non-channel region NC (excluding the two regions B) is disposed on the second portion 212 and the first opening 213. A part of the active layer 22 overlaps the first opening 213, and of course, the overlap between them is not limited in size in this invention. Favorably, the overlap is corresponding to the non-channel region NC. The second width W2 of the second portion 212 is 2 μm˜20 μm and favorably 4 μm˜15 μm.

Favorably, a gate insulation layer GI is disposed between the gate line region 21 and the active layer 22 so as to avoid a short circuit resulted from the contact of the gate line region 21 with the active layer 22. Besides, the material of the active layer 22 of this embodiment is oxide semiconductor, which is, for example but not limited to, crystalline or non-crystalline IGZO (Indium gallium zinc oxide).

Since the oxide semiconductor is used as the material of the active layer 22, an etch stop layer 23 is disposed on the active layer 22 to protect the active layer 22. In detail, during the etch process to from the first source/drain layer 24 and the second source/drain layer 25, the etch stop layer 23 can provide the function against the etch to prevent the active layer 22 from being damaged. Moreover, the first source/drain layer 24 and the second source/drain layer 25 are connected to the active layer 22 through the etch stop layer 23. Favorably, a part of the first source/drain layer 24 and a part of the second source/drain layer 25 contact the active layer 22 through the etch stop layer 23, which is denoted by the region B in FIG. 3A. In addition to preventing the active layer 22 from being damaged by the etch effect, the etch stop layer 23 also can define the etch locations of forming the first source/drain layer 24 and the second source/drain layer 25, and therefore the first source/drain layer 24 and the second source/drain layer 25 can certainly contact the active layer 22, providing a sound switch on of current at a particular time. Like the gate line region 21, the first source/drain layer 24 and the second source/drain layer 25 also use metal material, so the first source/drain layer 24 and the second source/drain layer 25 are usually called the second metal layer, corresponding to the gate line region 21 called the first metal layer.

Moreover, the pixel 2 further includes a first insulation layer BP1, a pixel electrode layer 26, a common electrode layer 27, a planar layer 28 and a second insulation layer BP2. The first insulation layer BP1 is disposed on the etch stop layer 23, the first source/drain layer 24 and the second source/drain layer 25, and the location of the first insulation layer BP1 corresponding to the second source/drain layer 25 forms a contact hole Via. The pixel electrode layer 26 connects to the second source/drain layer 25 through the contact hole Via. The common electrode layer 27 is disposed corresponding to the pixel electrode layer 26. The planar layer 28 is disposed between the first insulation layer BP1 and the common electrode layer 27. The second insulation layer BP2 is disposed between the pixel electrode layer 26 and the common electrode layer 27.

By referring to FIG. 3B also, in this embodiment, the first opening 213 is disposed at the location opposite to the location between the first source/drain layer 24 and the second source/drain layer 25 and extended to the side of the first source/drain layer 24 or the side of the second source/drain layer 25. In other words, the first opening 213 is disposed on the outside of the first source/drain layer 24 and the second source/drain layer 25 and is extended towards the first source/drain layer 24 or the second source/drain layer 25 of the adjacent pixel 2. Accordingly, the first opening 213 is disposed between the first source/drain layer 24 and the second source/drain layer 25 of the two adjacent pixels 2 and also between the two adjacent channel regions C, i.e. the portion of the non-channel region NC.

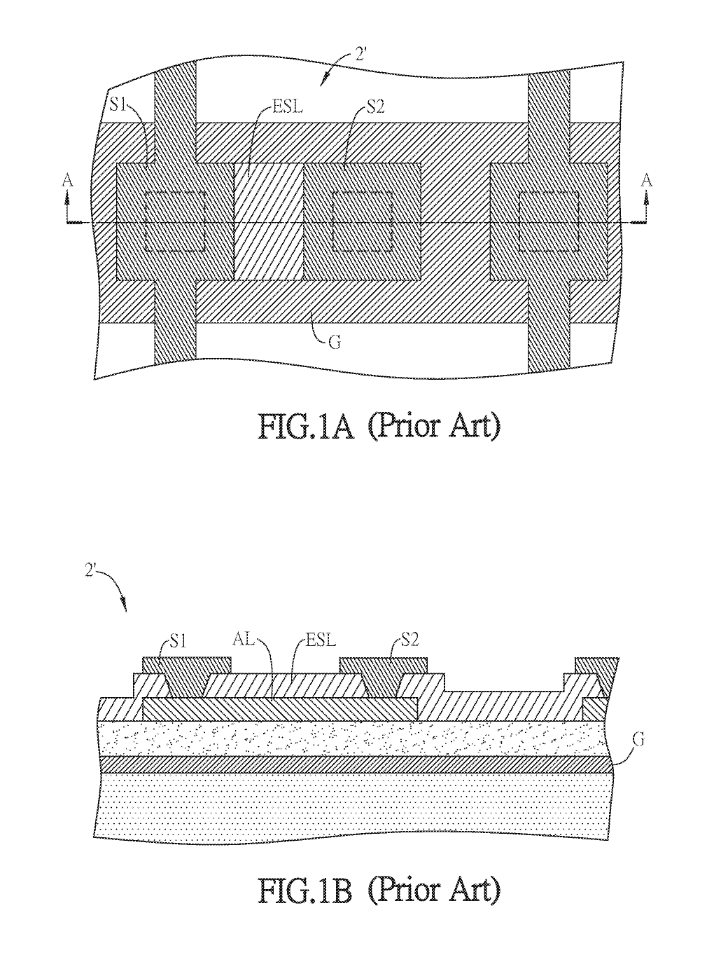

In the first embodiment, the gate line region 21 of the pixel 2 has the first opening 213, so the overlap area of the first source/drain layer 24 and the second source/drain layer 25 with the gate line region 21 is decreased. That means the overlap area of the gate with the source and the drain in this invention is less, in comparison with the conventional panel (as the gate G, the source S1 and the drain S2 as described in FIGS. 1A and 1B) so that the loading capacitance can be reduced. Accordingly, the display panel P configured with the pixel 2 of the first embodiment of the invention can be reduced in power consumption (P) by about 14%, in comparison with the conventional display panel of the same specifications. In detail, for a 7 inch display panel with the resolution of 1200*1920 and 323 PPI (pixel per inch) according to the display panel P of the first embodiment, it can be obtained that the capacitances Cs and Cg of each pixel are 25.8 fF and 21.1 fF, respectively, and the power consumption can be derived as about 935 mW from the calculation according to the foregoing formula, with the decrement of about 14% in comparison with the power consumption of 1088 mW of the conventional panel of the same specifications.

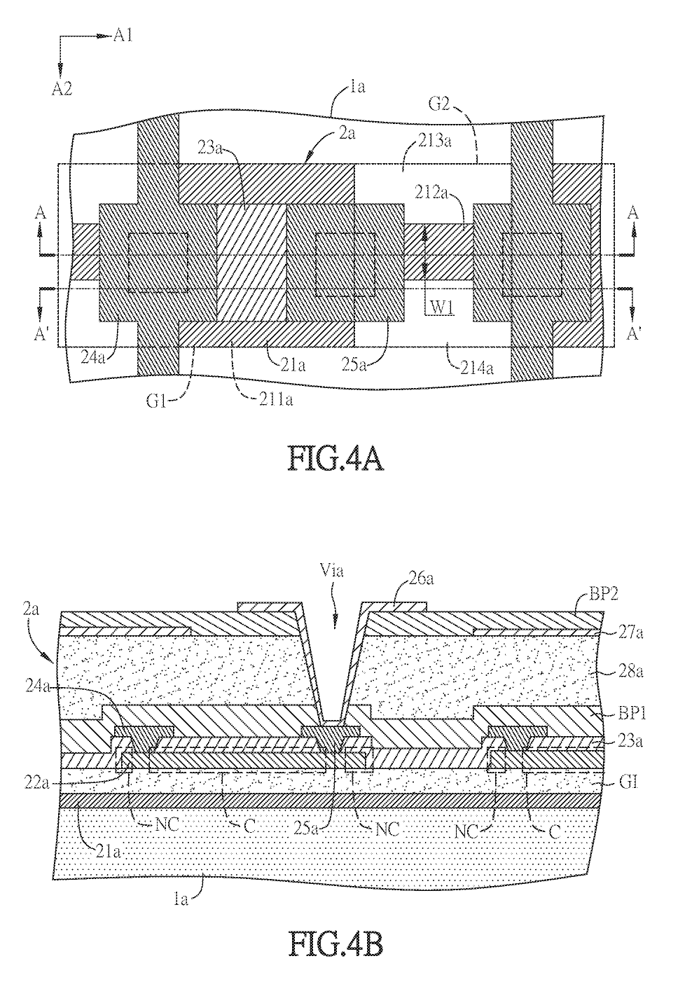

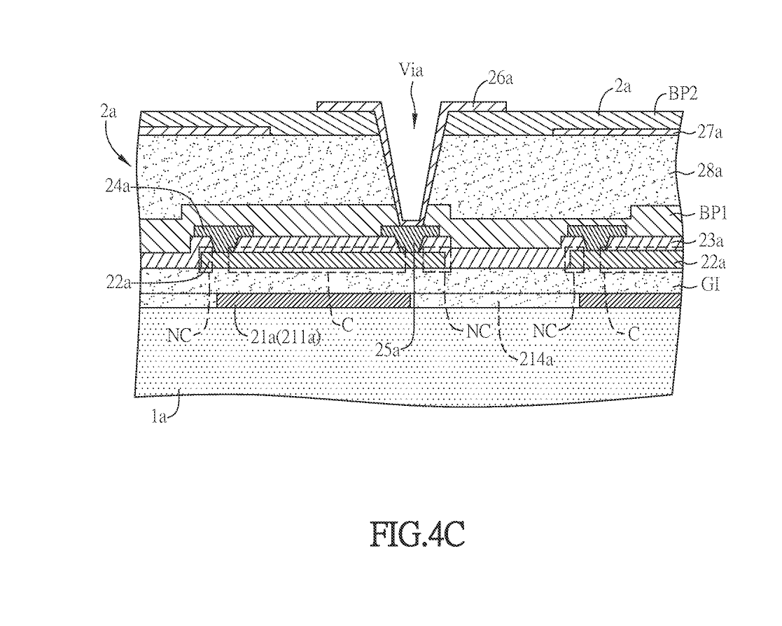

In the first embodiment, the first opening 213 of the second region G2 of the gate line region 21 is just formed on a single side of the second portion 212. Of course, the second portion 212 is unnecessarily just formed on the edge of the gate line region 21 in this invention. In other embodiments, by referring to FIG. 4A, the second portion 212 also can be disposed at the center of the gate line region 21 so that the openings can be formed on two sides of the second portion 212.

FIG. 4A is a schematic top view of a part of the pixels and the first substrate in FIG. 2 according to the second embodiment of the invention, FIG. 4B is a schematic sectional diagram taken along the line A-A in FIG. 4A, and FIG. 4C is a schematic sectional diagram taken along the line A′-A′ in FIG. 4A. As shown in FIGS. 4A to 4C, the second region G2 of the gate line region 21a of the second embodiment can further have a second opening 214a. The first opening 213a and the second opening 214a have the same structure substantially, both are the openings, but they are given different denotations for clear illustration. The first opening 213a and the second opening 214a are disposed on the second region G2, so that the second portion 212a of the gate line region 21a is preserved. In other words, as shown in FIG. 4A, the first opening 213a and the second opening 214a are disposed on the opposite sides of the second portion 212a.

To be noted, the sizes of the first opening 213a and the second opening 214a are not particularly limited in this invention, as long as the second portion 212a is preserved to communicate with the gate line region 21a, and the first opening 213a and the second opening 214a are disposed between the two adjacent channel regions C and over the non-channel region NC. Favorably, the second width W2 of the second portion 212 of the second embodiment is 2 nm˜20 nm and favorably 4 nm 15 μm. Moreover, whether the first opening 213a and the second opening 214a are the same in size is not limited in the invention. In other words, the first opening 213a and the second opening 214a can have different sizes, and therefore the preserved second portion 212a is also not limited in location.

As shown in FIGS. 4A and 4C, the gate line region 21 of the pixel 2a has the first opening 213a and the second opening 214a, so that the overlap area of the first source/drain layer 24a and the second source/drain layer 25a with the gate line region 21a is decreased. Likewise, the effectiveness of reducing the loading capacitance can be achieved. Accordingly, the display panel P configured with the pixel 2a of the second embodiment can be reduced in power consumption (P) by about 10%, in comparison with the conventional display panel of the same specifications. In detail, for a 7 inch display panel with the resolution of 1200*1920 and 323 PPI (pixel per inch) according to the display panel P of the second embodiment, it can be obtained that the capacitances Cs and Cg of each pixel are 27.5 fF and 22.1 fF, respectively, and the power consumption can be derived as about 978 mW from the calculation according to the above-mentioned formula, with the decrement of about 10% in comparison with the power consumption of 1088 mW of the conventional panel of the same specifications. Other components of the display panel P of the second embodiment and the connection relation thereof can be comprehended by referring to the above-mentioned display panel P of the first embodiment and therefore are omitted here.

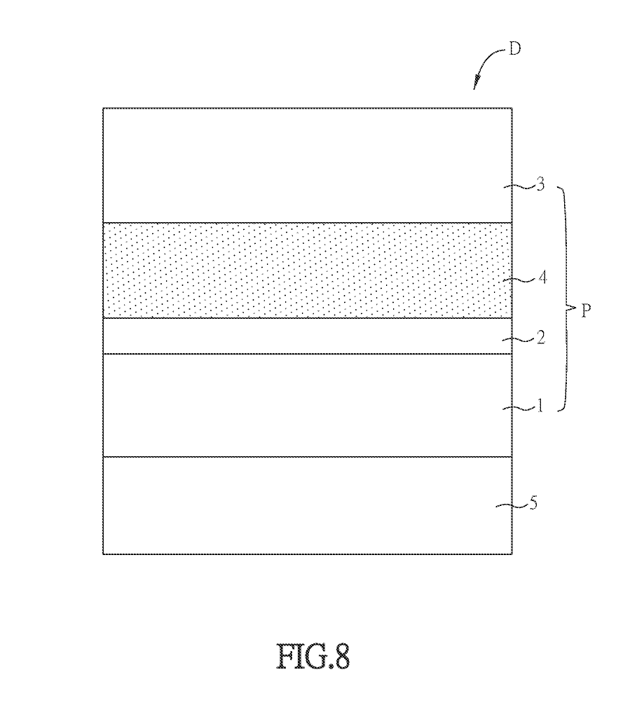

Accordingly, the gate line region 21 (or 21a) forms the first opening 213 (or 213a) or the second opening 214a which are disposed overlapping the non-channel region NC in the first and second embodiments, so the light of a backlight module 5 won't be emitted to the channel region C when the display panel P of the first or second embodiment is applied to the backlight module 5 (referring to FIG. 8), so that the switch on of current won't be affected. Moreover, the opening structure also can be formed in the first source/drain layer and the second source/drain layer so that the effectiveness of reducing the loading capacitance can be achieved and the power consumption of the pixel driving can be thus reduced.

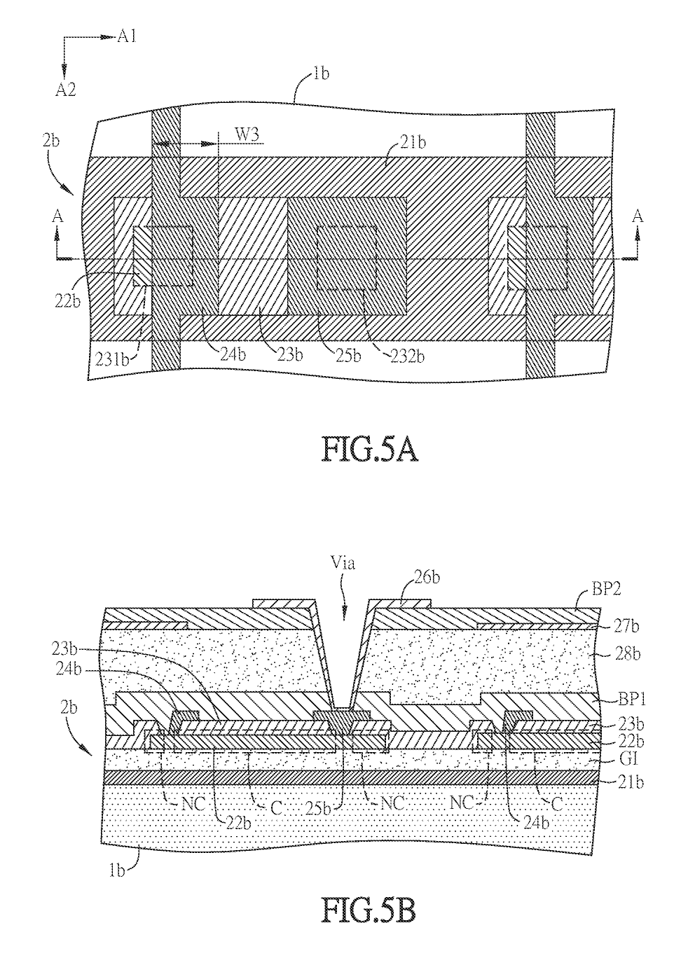

FIG. 5A is a schematic diagram of a part of the pixels and the first substrate in FIG. 2 according to the third embodiment of the invention, and FIG. 5B is a schematic sectional diagram taken along the line A-A in FIG. 5A. As shown in FIGS. 5A and 5B, the pixel 2b of the third embodiment also includes the gate line region 21b, an active layer 22b, an etch stop layer 23b, the first source/drain layer 24b, a second source/drain layer 25b and a first insulation layer BP1. The gate line region 21b is disposed on the first substrate 1b and extended along a first direction A1. The active layer 22b is disposed on the gate line region 21b. The etch stop layer 23b, the first source/drain layer 24b and the second source/drain layer 25b are disposed on the active layer 22b. The etch stop layer 23b has a first via 231b and a second via 232b. The first source/drain layer 24b is disposed in the first via 231b to connect to the active layer 22b, and the second source/drain layer 25b is disposed in the second via 232b to connect to the active layer 22b. In other words, the first source/drain layer 24b and the second source/drain layer 25b connect to the active layer 22b through the first via 231b and the second via 232b, respectively. The first insulation layer BP1 is disposed on the first source/drain layer 24b and the second source/drain layer 25b and is disposed in the first via 231b to contact the active layer 22b.

From the experiment, it can be known that the electric property of the thin film transistor won't be influenced if the non-channel region of the active layer is etched by the etchant. Accordingly, in this embodiment, the portion of the first source/drain layer 24b corresponding to the non-channel region NC can be removed, so that the non-channel region NC of the active layer 22b is revealed by the edge of the removed portion of the first source/drain layer 24b and the portion of the first insulation layer BP1 disposed in the first via 231b is disposed on the non-channel region NC. Favorably, the first source/drain layer 24b has a third width W3 of 5 μm˜8.5 μm along the first direction A1, and in other words, the portion of the first source/drain layer 24b that is not removed has a third width W3 of 5 μm˜8.5 μm.

The pixel 2b of this embodiment also includes the pixel electrode layer 26b, which is disposed on the first insulation layer BP1 and contacts the second source/drain layer 25b. Besides, the pixel electrode layer 26b is disposed on the non-channel region NC. The main components of the pixel 2b and the relation thereof can be comprehended by referring to the foregoing illustration and are omitted here therefore.

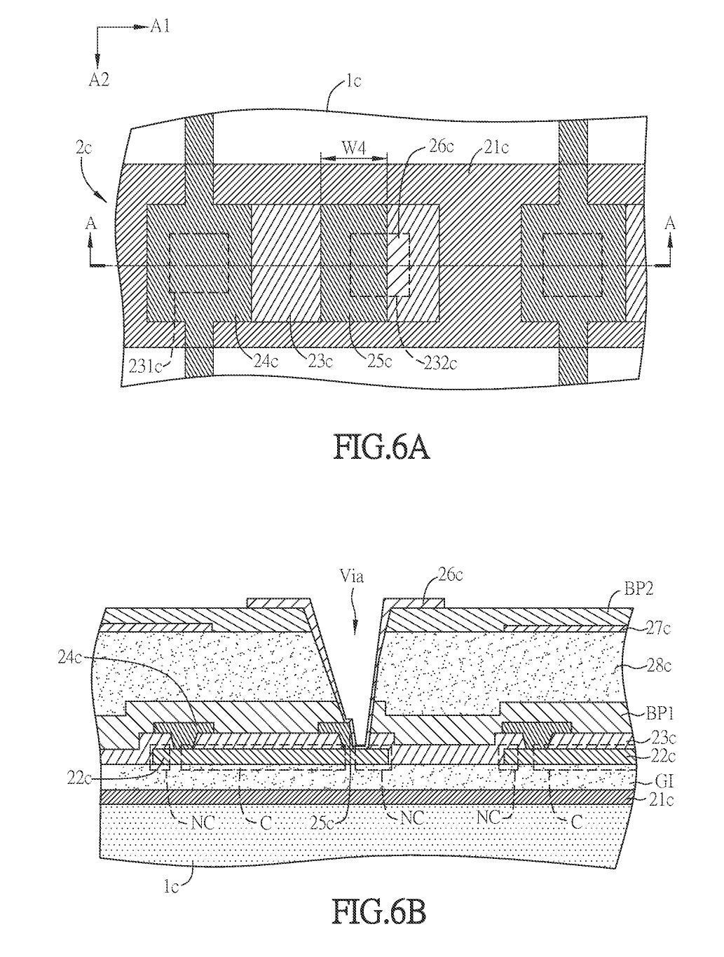

FIG. 6A is a schematic diagram of a part of the pixels and the first substrate in FIG. 2 according to the fourth embodiment of the invention, and FIG. 6B is a schematic sectional diagram taken along the line A-A in FIG. 6A. As shown in FIGS. 6A and 6B, the pixel 2c of the fourth embodiment also includes the gate line region 21c, an active layer 22c, an etch stop layer 23c, the first source/drain layer 24c, a second source/drain layer 25c, a first insulation layer BP1 and a pixel electrode layer 26c. The disposition of the gate line region 21c, the active layer 22c, the etch stop layer 23c, the first source/drain layer 24c and second source/drain layer 25c can be comprehended by referring to the third embodiment and is omitted here therefore. The first insulation layer BP1 is disposed on the first source/drain layer 24c and the second source/drain layer 25c. The pixel electrode layer 26c is disposed on the first insulation layer BP1 and disposed in the second via 232c to contact the active layer 22c.

Therefore, in this embodiment, the portion of the second source/drain layer 25c corresponding to the non-channel region NC can be removed, so that the non-channel region NC of the active layer 22c is revealed by the edge of the removed portion of the second source/drain layer 25c and the portion of the pixel electrode layer 26c disposed in the second via 232c is disposed on the non-channel region NC. Favorably, the second source/drain layer 25c has a fourth width W4 of 5 nm˜8.5 nm along the first direction A1, and in other words, the portion of the second source/drain layer 25c that is not removed has a fourth width W4 of 5 nm˜8.5 nm.

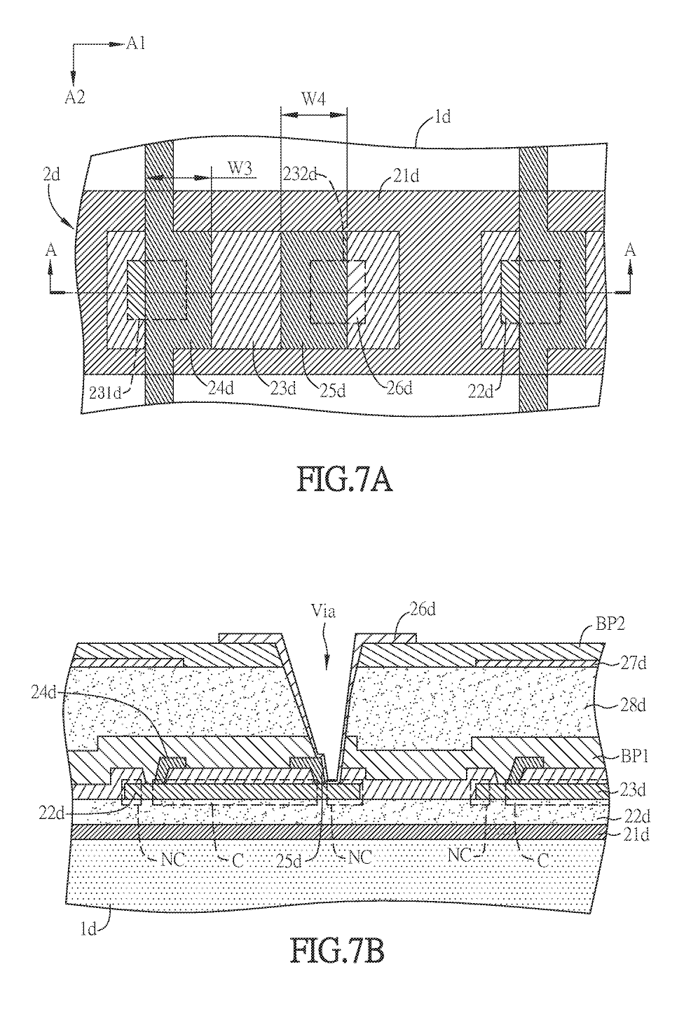

FIG. 7A is a schematic diagram of a part of the pixels and the first substrate in FIG. 2 according to the fifth embodiment of the invention, and FIG. 7B is a schematic sectional diagram taken along the line A-A in FIG. 7A. As shown in FIGS. 7A and 7B, the fifth embodiment is the combination of the third and fourth embodiments. Accordingly, the first insulation layer BP1 is disposed in the first via 231d to contact the active layer 22d and the pixel electrode layer 26d is disposed in the second via 232d to contact the active layer 22d. In other words, the portions of the first and second source/drain layers 24d and 25d corresponding to the non-channel region NC are both removed, so that the non-channel region NC of the active layer 22d is revealed by the edges of the removed portions of the first and second source/drain layers 24d and 25d.

In the display panel P configured with the pixel 2b (2c, 2d) of the third to fifth embodiments of the invention, the portion of one of the first source/drain layer 24b (24c, 24d) and the second source/drain layer 25b (25c, 25d) corresponding to the non-channel region NC is removed, so the overlap area of the first source/drain layer 24b (24c, 24d) and the second source/drain layer 25b (25c, 25d) with the gate line region 21b (21c, 21d) can be decreased. Likewise, that means the loading capacitance can be reduced. Accordingly, the display panel P of the fifth embodiment can be reduced in power consumption (P) by about 21%, in comparison with the conventional display panel of the same specifications. In detail, for a 7 inch display panel with the resolution of 1200*1920 and 323 PPI (pixel per inch) according to the display panel P of the fifth embodiment, it can be obtained that the capacitances Cs and Cg of each pixel are 24.9 fF and 19.3 fF, respectively, and the power consumption can be derived as about 858 mW from the calculation according to the foregoing formula, with the drop of about 21% in comparison with the power consumption of 1088 mW of the conventional panel of the same specifications.

FIG. 8 is a schematic sectional diagram of a display device according to an embodiment of the invention. As shown in FIG. 8, a display device D includes a display panel P and a backlight module 5, and the display panel P is disposed on the backlight module 5. The display panel P can be comprehended by referring to the first to fifth embodiments and is omitted here therefore. The backlight module 5 can include, for example, cold cathode fluorescent lamp (CCFL), hot cathode fluorescent lamp (HCFL) or light emitting diode (LED). However, this invention is not limited thereto.

Summarily, in the display panel and display device of the invention, the gate line region is divided into the first region and the second region, which include the first portion and the second portion, respectively, and the first width of the first portion is greater that the second width of the second portion. Or, the first insulation layer is disposed in the first via of the etch stop layer to contact the active layer. Or, the pixel electrode layer is disposed in the second via of the etch stop layer to contact the active layer. Accordingly, the overlap area of the first and second source/drain layers with the gate line region is reduced and less, in comparison with the overlap area of the source and drain with the gate of the conventional display panel. Therefore, the effectiveness of reducing the loading capacitance can be achieved, and the power consumption of the pixel driving can be thus reduced and the driving signals can be stabilized, so that the display panel and device wont′ easily undergo the problem of abnormal display and display distortion.

Moreover, the location of the second portion, the location of the first insulation layer contacting the active layer and the location of the pixel electrode layer contacting the active layer are all corresponding to the non-channel region, so the switch on of current in the channel region won't be influenced and the original current-voltage property can be thus kept.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display panel, comprising:
a first substrate;
a plurality of pixels disposed on the first substrate, at least one of the pixels comprising:
a gate line region disposed on the first substrate and extended along a first direction and including a first region and a second region, wherein the first region includes a first portion and the second region includes a second portion, the first portion and the second portion have a first width and a second width along a second direction, respectively, the first direction is perpendicular to the second direction and the first width is greater than the second width;
an active layer disposed on the gate line region and including a channel region disposed on the first portion;
an etch stop layer disposed on the active layer; and
a first source/drain layer and a second source/drain layer disposed on the active layer and connected to the active layer, wherein the portion of the active layer between the first source/drain layer and the second source/drain layer is the channel region;
a second substrate disposed on the first substrate; and
a display medium disposed between the first and second substrates.

2. The display panel as recited in claim 1, wherein the active layer further includes a non-channel region, the second region further has a first opening, and the non-channel region is disposed on the first opening.

3. The display panel as recited in claim 1, wherein the active layer further includes a non-channel region, which is disposed on the second portion.

4. The display panel as recited in claim 3, wherein the second region further has a second opening.

5. The display panel as recited in claim 1, wherein the second width is 2 μm˜20 μm.

6. The display panel as recited in claim 5, wherein the second width is 4 μm˜15 μm.

7. A display panel, comprising:
a first substrate;
a plurality of pixels disposed on the first substrate, at least one of the pixels comprising:
a gate line region disposed on the first substrate and extended along a first direction;
an active layer disposed on the gate line region;
an etch stop layer disposed on the active layer and having a first via and a second via;
a first source/drain layer disposed on the active layer and disposed in the first via to connect to the active layer;
a second source/drain layer disposed on the active layer and disposed in the second via to connect to the active layer; and
a first insulation layer disposed on the first source/drain layer and the second source/drain layer and disposed in the first via;
a second substrate disposed on the first substrate; and
a display medium disposed between the first and second substrates.

8. The display panel as recited in claim 7, wherein the portion of the active layer between the first source/drain layer and the second source/drain layer is a channel region, the active layer further includes a non-channel region, and the portion of the first insulation layer disposed in the first via is disposed on the non-channel region.

9. The display panel as recited in claim 7, wherein at least one of the pixels further includes a pixel electrode layer disposed on the first insulation layer and in the second via.

10. The display panel as recited in claim 9, wherein the portion of the active layer between the first source/drain layer and the second source/drain layer is a channel region, the active layer further includes a non-channel region, and the portion of the pixel electrode layer disposed in the second via is disposed on the non-channel region.

11. The display panel as recited in claim 7, wherein the first source/drain layer has a third width of 5 μm˜8.5 μm along the first direction.

12. A display panel, comprising:
a first substrate;
a plurality of pixels disposed on the first substrate, at least one of the pixels comprising:
a gate line region disposed on the first substrate and extended along a first direction;
an active layer disposed on the gate line region;
an etch stop layer disposed on the active layer and having a first via and a second via;
a first source/drain layer disposed on the active layer and disposed in the first via to connect to the active layer;
a second source/drain layer disposed on the active layer and disposed in the second via to connect to the active layer;
a first insulation layer disposed on the first source/drain layer and the second source/drain layer; and
a pixel electrode layer disposed on the first insulation layer and in the second via;
a second substrate disposed on the first substrate; and
a display medium disposed between the first and second substrates.

13. The display panel as recited in claim 12, wherein the portion of the active layer between the first source/drain layer and the second source/drain layer is a channel region, the active layer further includes a non-channel region, and the portion of the pixel electrode layer disposed in the second via is disposed on the non-channel region.

14. The display panel as recited in claim 12, wherein the first insulation layer is disposed in the first via.

15. The display panel as recited in claim 14, wherein the portion of the active layer between the first source/drain layer and the second source/drain layer is a channel region, the active layer further includes a non-channel region, and the portion of the first insulation layer disposed in the first via is disposed on the non-channel region.

16. The display panel as recited in claim 12, wherein the second source/drain layer has a fourth width of 5 μm˜8.5 μm along the first direction.
